(19) United States
(12) Patent Application Publication
(10) Pub. No.: US 2018/0027193 A1
(43) Pub. Date: Jan. 25, 2018

(54) QUANTUM FILM PIXELS WITH LOW READOUT NOISE

(71) Applicant: INVISAGE TECHNOLOGIES, INC., Newark, CA (US)

(72) Inventors: Nikolai Bock, San Jose, CA (US); Emanuele Mandelli, Mountain View, CA (US); Zach M. Beiley, Oakland, CA (US); Jae Park, Newark, CA (US)

(21) Appl. No.: 15/657,068

(22) Filed: Jul. 21, 2017

Related U.S. Application Data
(60) Provisional application No. 62/365,929, filed on Jul. 22, 2016.

(51) Int. Cl. H04N 5/357; H01L 27/146; H04N 5/3745

(52) U.S. Cl. CPC H04N 5/3575; H04N 5/37452; H01L 27/14636; H01L 27/1461; H01L 27/14609; H01L 27/14614; H01L 27/1462; H01L 31/035218

(57) ABSTRACT

Generally discussed herein are imaging devices and corresponding circuitry and methods of using and making the same. An image sensor device may include pixel circuitry, the pixel circuitry comprising a photosensitive material layer, circuitry including first, second, and third electrodes and a storage device, the first electrode on a first surface of the photosensitive material layer and the second and third electrodes on a second surface of the photosensitive material layer, the first surface opposite the second surface, electrical interconnect circuitry electrically coupling the second electrode and the storage device, and a dielectric material situated between the third electrode and the photosensitive material layer.

### RELATED APPLICATION

This application claims the benefit of priority of U.S. Provisional Application Ser. No. 62/365,929, filed Jul. 22, 2016 and titled “QUANTUM FILM PIXELS WITH LOW READOUT NOISE”, which is incorporated herein by reference in its entirety.

### BACKGROUND

Light sensors are used to detect information regarding a scene, a surrounding, gestures, movements, signals, reflections, and the like. Image sensors typically include arrays of light sensing devices. An image sensor converts light incident thereon to an array of digital or analog signals that represent colors and/or intensity of pixel values. The pixel values represent the image.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates, by way of example, a diagram of an embodiment of circuitry of an image sensing device.

FIG. 2 illustrates, by way of example, a diagram of an embodiment of pixel circuitry.

FIG. 3 illustrates, by way of example, a diagram of another embodiment of pixel circuitry.

FIG. 4 illustrates, by way of example, a diagram of a graph of voltage versus time for a variety of signals.

FIG. 5 illustrates, by way of example, a diagram of an embodiment of circuitry of an image sensing device.

FIG. 6 illustrates, by way of example, a cross-section diagram of an embodiment of circuitry of FIG. 5 from a viewpoint of arrows labelled “6”.

FIG. 7 illustrates, by way of example, a cross-section diagram of an embodiment of circuitry of FIG. 5 from a viewpoint of arrows labeled “7”.

FIG. 8 illustrates, by way of example, an energy band diagram of an image sensor pixel as described here.

FIG. 9 illustrates, by way of example, a top view of the electrodes of pixel of an image sensing device as described here.

FIG. 10 illustrates, by way of example, a top view of the electrodes of pixel of an image sensing device as described here.

FIG. 11 illustrates, by way of example, a top view of the electrodes of a shared pixel of an image sensing device as described here.

FIG. 12 illustrates, by way of example, a top view of the electrodes of a shared pixel of an image sensing device as described here.

FIG. 13 illustrates, by way of example, a diagram of embodiment of pixel circuitry.

FIG. 14 illustrates, by way of example, a diagram of embodiment of pixel circuitry.

FIG. 15 illustrates an example of a variety of voltages versus time corresponding to rolling shutter mode.

FIG. 16 illustrates an example of a variety of voltages versus time corresponding to global shutter mode.

### DETAILED DESCRIPTION

Described here are image sensors comprising a plurality of pixels, where each pixel utilizes a plurality of electrodes in conjunction with an optically-sensitive material positioned on a semiconductor-based readout circuit. Image sensors can be made using a semiconductor-based strategy in which transistors, diodes, and photodiodes are formed in or on a semiconductor substrate, for example, and are suitably connected to form both light sensors and circuits for their readout. These image sensors are formed using a semiconductor-based readout circuit, which may be coated using an optically-sensitive material. Pixel electrodes atop the semiconductor substrate-based readout circuit may be in electrical communication with the optically sensitive material. The pixel electrode for a given pixel may provide biasing of the optically-sensitive material at that pixel, and collection of photocurrent from the optically sensitive material at that pixel. A second electrode, or class of electrodes, can be used to provide the second electrical potential for continuity of current, and for application of a chosen bias across the pixels formed by the combination at a given pixel of (a) the first (i.e., pixel) electrode, (b) the optically-sensitive material, and (c) the second electrode. Furthermore, a pixel in the image sensors described here may have one or more additional electrodes beyond the first and second electrodes which may assist in the operation of the readout circuitry as discussed in more detail below. In various embodiments, the disclosed subject matter includes, for example, light sensors comprising (a) a first electrode; (b) an optically-sensitive material; (c) a second electrode; (d) a third electrode; and (e) optionally fourth and additional electrodes.

Reference will now be made to the figures to describe further details and embodiments. Additionally, U.S. Pat. No. 7,923,801, granted 12 Apr. 2011 and entitled, “Materials, Systems and Methods for Optoelectronic Devices” is hereby incorporated by reference in its entirety.

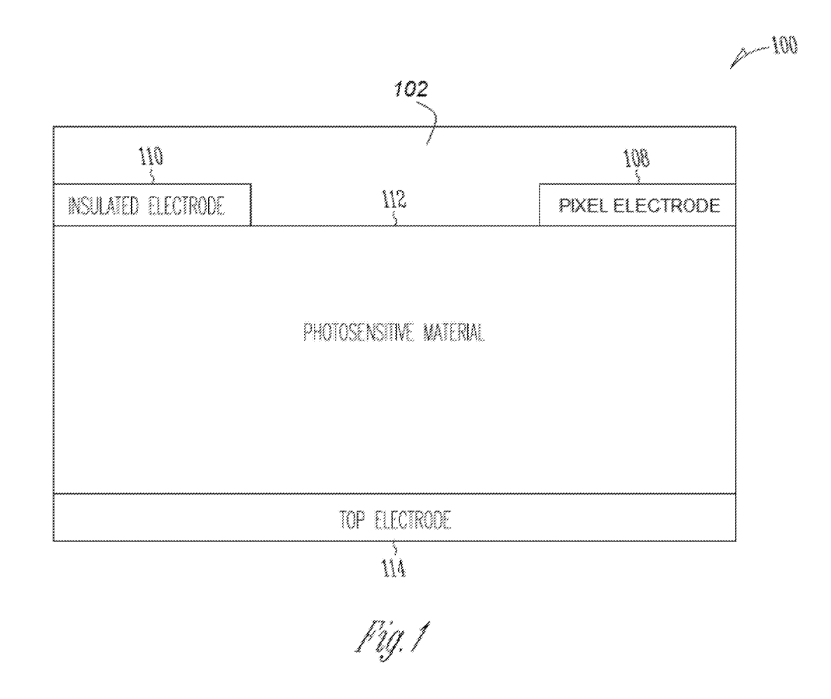

FIG. 1 illustrates, by way of example, a diagram of an embodiment of a pixel of an image sensing device 100. The pixel of the device 100 as illustrated includes readout circuitry 102, a photosensitive material layer 112, a pixel electrode 108, an insulated storage electrode 110, and a top electrode 114. The photosensitive material layer 112 may be positioned in another plane from the readout circuitry 102, and the pixel electrode 108 and the insulated storage electrode 110 may each be positioned at an interface between the photosensitive material layer 112 and the readout circuitry 102. In some embodiments, the image sensing device 100 may further comprise one or more additional electrodes, such as electrodes operate as a transfer electrode or a barrier electrode.

The readout circuitry 102 can include a semiconductor layer and/or one or more metal layers (collectively referred to herein as a “metal stack”) which collectively perform biasing, readout, and resetting operations of the image sensor. The semiconductor layer may include a semiconductor, such as silicon, germanium, indium, arsenic, aluminum, boron, gallium, nitrogen, phosphorus, doped versions thereof, or a combination thereof. In one or more embodiments, the substrate 102 includes an indirect-bandgap semiconductor (e.g., silicon, germanium, aluminum-antimonide, or the like). In instances where the readout circuitry comprises a metal stack, the metal layers may be patterned to form contacts, vias, or other conductive pathways which may be insulated by a dielectric such as SiO₂. The readout circuitry 102 may include materials that are readily available and manipulatable, such as in manufacturing. The readout circuitry 102 can include electronic properties for forming circuitry of an image sensor. The readout circuitry 102 may facilitate maintaining stored charges, such as when in an excited state (e.g., when a suitable voltage is applied to one or more of the electrodes).

The control circuitry 106 can further include a barrier gate connected to a barrier electrode, a reset switch, a select switch, a charge follower switch, and/or a transfer gate connected to a transfer electrode, as will be discussed in more detail below.

The readout circuitry 102 may comprise a charge sense node, which may be coupled to the pixel electrode 108. The pixel electrode 108 may be conductively coupled to the photosensitive material layer 112 such that the pixel electrode 108 provides a direct current pathway from the photosensitive material layer 112 to the charge sense node. The charge sense node may be read out during imaging, as discussed in more detail below. In some instances, the pixel electrode 108 can include a semiconductor at an interface between the pixel electrode 108 and the photosensitive material layer 112, and in some instances the semiconductor may be selected such that the semiconductor forms a heterojunction with the photosensitive material layer.

The readout circuitry 102 may further comprise a storage gate, which may provide a bias to the insulated storage electrode 110. When a bias is applied to the insulated storage electrode 110, the electrode 110 may act as a storage electrode. Specifically, the bias may influence the electric field within one or more portions of the photosensitive material layer 112 such that charge accumulated in the photosensitive material layer 112 may be temporarily held near the insulated electrode. To facilitate this temporary storage, the insulated storage electrode 110 may comprise an electrode that is electrically isolated from the photosensitive material layer 112 by an insulating material such that the electrode 110 may be capacitively coupled to the photosensitive material layer 112.

To the extent that a pixel comprises a transfer electrode (which may be capacitively coupled to the photosensitive material layer 112), the readout circuitry 102 for that pixel may further comprise a transfer gate which may be used to bias the transfer electrode. Additionally or alternatively, if a pixel comprises a barrier electrode (which may be capacitively coupled to the photosensitive material layer 112), the readout circuitry 102 may further comprise a barrier gate, which may be used to bias the transfer electrode. These gates, as well as other components of the readout circuitry 102 will be discussed in more detail below.

When electrodes are discussed here as being “conductively coupled” to the photosensitive material layer 112, it should be appreciated that the electrodes provide a direct electrical conduction pathway between the photosensitive material layer 112 and the electrode such that direct current may flow between the photosensitive material layer 112 and the electrode during operation of the image sensor. For example, the electrode may be configured to create an Ohmic contact between the electrode and the photosensitive material layer 112. In these embodiments, it may be desirable for the photosensitive material layer 112 and the electrode to have similar work functions. As an example, if the photosensitive material layer includes a p-type semiconductor that has a work function that is approximately as deep as the work function of the electrode, then holes may readily flow from the electrode to the photosensitive material layer 112 (or vice versa). Alternatively, the electrode may be configured such there is selective current flow between the electrode and the photosensitive material layer 112. As an example, if an electrode is selected to have a work function that is sufficiently shallower than the work function of the photosensitive material layer 112, the resultant work function difference may produce a selective barrier such that photoelectrons created in the photosensitive material layer 112 may be drawn into the relatively-shallow-work-function electrode, whereas holes may be blocked from egress into the relatively-shallow-work-function electrode.

Conversely, when electrodes are described here as being “capacitively coupled” to the photosensitive material layer 112, that electrode is not directly conductively-coupled to photosensitive material layer 112, but is in sufficient proximity to photosensitive material layer 112 that when biased may influence a profile of an electric field within the photosensitive material layer 112. An insulator such as a dielectric material may separate the conductive portion of the electrode from the photosensitive material layer 112, which may act to prevent direct current flow between the electrode and the photosensitive material layer 112 during operation of the image sensor. While ideally no direct current would flow between the electrode and the photosensitive material layer 112, it should be appreciated that in practice there may be leakage current due to imperfections in the insulator, and this leakage current would not be considered direct current for the purposes of distinguishing a “capacitively coupled” electrode from a “conductively coupled” electrode. When an electrode is capacitive coupling to the photosensitive material layer 112, the placement of a charge of one sign the electrodes may induce a comparable amplitude, but of opposite sign, in regions of the photosensitive material layer 112 that are most proximate the electrode.

Returning to FIG. 1, the photosensitive material layer 112 may be configured to absorb photons and generate one or more electron-hole pairs in response to photon absorption. In some instances, the photosensitive material layer 112 may include one or more films formed from quantum dots, such as those described in U.S. Pat. No. 7,923,801, which was previously incorporated by reference in its entirety. The materials of photosensitive material layer 112 may be tuned to change the absorption profile of the photosensitive material layer 112 such that the image sensor may be configured to absorb light of certain wavelengths (or range of wavelengths) as desired. It should be appreciated that while discussed and typically shown as a single layer, the photosensitive material layer may be made from a plurality of sub-layers. For example, the photosensitive material layer may comprise a plurality of distinct sub-layers of different photosensitive material layers that have different photoconductive layer materials.

Additionally or alternatively, the photosensitive material layer 112 may include one or more sub-layers that perform additional functions such as providing chemical stability, adhesion or other interface properties between the photosensitive material layer 112 and the readout circuitry 102, or for facilitate charge transfer laterally across the photosensitive material layer 112. It should be appreciated that sub-layers of the photosensitive material layer 112 may optionally be patterned such that different portions of the readout circuitry 102 may interface with different materials of the photosensitive material layer 112. For example, the pixel electrode 108 may interface with a first sub-layer of the photosensitive material layer 112 and the insulator of the insulated storage electrode 110 may interface with a different sub-layer of the photosensitive material layer 112. For the purposes of discussion in this application, the photosensitive material layer 112 will be discussed as a single layer, although it should be appreciated that a single layer or a plurality of different sub-layers may be selected based on the desired makeup and performance of the image sensor.

To the extent that the image sensor 100 comprises a plurality of pixels, in some instances a common portion of the photosensitive material layer 112 may laterally span multiple pixels of the image sensor. Additionally or alternatively, the photosensitive material layer 112 may be patterned 112 such that different segments of the photosensitive material layer 112 may overlay different pixels (such as an embodiment in which each pixel has its own individual segment of the photosensitive material layer 112). As mentioned above, photosensitive material layer 112 may be in a different plane than the readout circuitry 102, such as to above or below the readout circuitry 102 relative to light incident thereon. That is, the light may contact the photosensitive material layer 112 without passing through a plane (generally parallel to a surface of the photosensitive material layer) in which the readout circuitry resides.

In some instances, it may be desirable for the photosensitive material layer 112 to comprise one or more direct bandgap semiconductor materials while the readout circuitry 102 comprises an indirect bandgap semiconductor. Examples of direct bandgap materials include indium arsenide and gallium arsenide, among others. The bandgap of a material is direct if a momentum of holes and electrons in a conduction band is the same as a momentum of holes and electrons in a valence band. Otherwise, the bandgap is an indirect bandgap. In embodiments that include readout circuitry 102 that includes an indirect bandgap semiconductor and a photosensitive material layer 112 that includes a direct bandgap semiconductor, the photosensitive material layer 112 may promote light absorption and/or reduce pixel-to-pixel cross-talk, while the readout circuit 102 may facilitate storage of charge while reducing residual charge trapping.

While the pixel electrode 108 and the insulating storage electrode 110 are shown in FIG. 1 to interface with a first side of the photosensitive material layer 112, the electrode 114 may be positioned on an opposite side of the photosensitive material layer 112 such that the photosensitive material layer 112 is positioned between the electrode 114 and each of the pixel electrode 108 and storage electrode 110. As used herein, the electrode 114 can be referred to as a “top electrode”. Generally, the image sensor is positioned within an imaging device such that oncoming light passes through the top electrode 114 before reaching the photosensitive material layer 112. Accordingly, it may be desirable for the top electrode 114 to be formed from a conductive material that is transparent to the wavelengths of light that the image sensor is configured to detect. For example, the top electrode 114 may comprise a transparent conductive oxide. In some instances, the electrode 114 may span multiple pixels of an image sensor. Additionally or alternatively, the electrode 114 optionally may be patterned into individual electrodes 114 such that different pixels have different top electrodes. For example, there may be a single top electrode that addresses every pixel of the image sensor, one top electrode per pixel, or a plurality of top electrodes where at least one top electrode address multiple pixels.

While the top electrode in FIG. 1 may be made from a transparent conductive material, it should be appreciated that other electrodes may not be transparent and may be formed from any suitable conductive material (e.g., copper, gold, aluminum, platinum, a combination thereof, or the like).

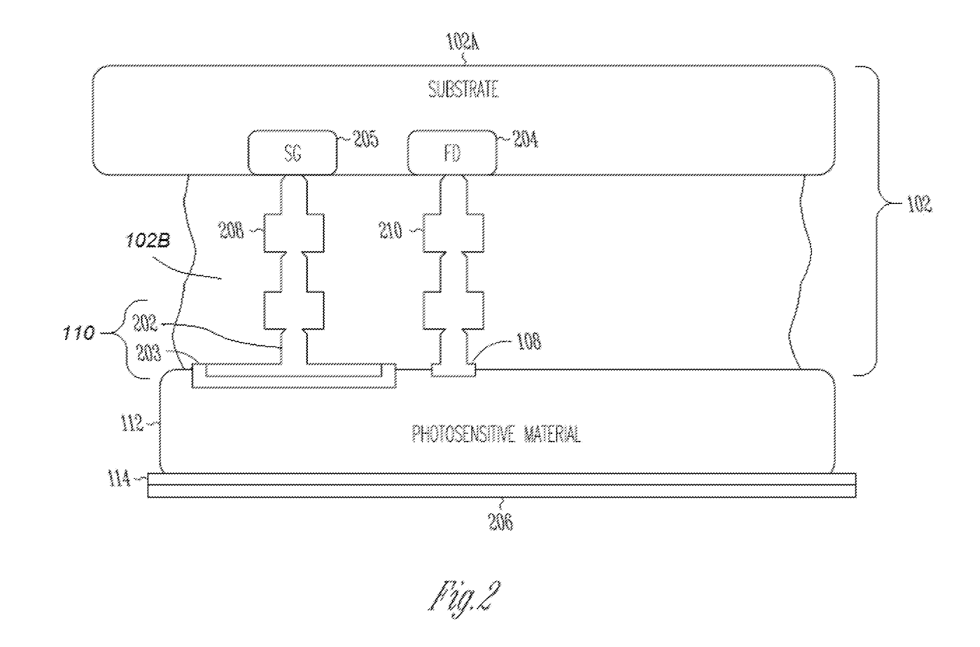

Although not shown in FIG. 1 (but shown in FIG. 2 as 206), the image sensor device may optionally further comprise one or more encapsulant layers on an upper surface of image sensor (e.g., on top of the photosensitive material layer 112 and/or top electrodes 114). The encapsulant may preferably be transparent to the wavelengths intended to be measured by the image sensor, and may be configured to help prevent reactive gases such as oxygen and water from permeating the photosensitive material layer 112. In some instances the encapsulant may act as an anti-reflective coating.

FIG. 2 illustrates, by way of example, a diagram of one embodiment of a pixel of an image sensor having multi-electrode control. The pixel, as illustrated, includes readout circuitry 102, a photosensitive material layer 112, an insulated storage electrode 110, a pixel electrode 108, and a top electrode 114. In the embodiment shown in FIG. 2, the readout circuitry 102 may comprise a substrate 102A and a metal stack 102B. The substrate 102A, which may be a semiconductor substrate as discussed above, may comprise a sense node 204 and a storage gate 205. The metal stack 102B may comprise a first interconnect circuitry 208 that electrically couples the storage gate 205 to the insulated storage electrode 110, and second interconnect circuitry 210 that electrically couples the pixel electrode 108 to the charge sense node 204. The first and second interconnect circuitry may comprise a conductive material (which may or may not be the same material as the conductive portions of the pixel and insulated storage electrodes) and be insulated from each other by a dielectric, such as SiO₂ or other suitable dielectric. It should be appreciated that the metal stack 102B and the associated interconnect circuitry may be formed using traditional a complementary metal-oxide semiconductor (CMOS) processes. Also shown in FIG. 2 is an optional encapsulant material 206, such as discussed in more detail above.

The insulated electrode 110 may comprise a conductive portion 202 separated from the photosensitive material layer 112 by an insulating layer 203 (which may be a dielectric, such as SiO₂ or other suitable dielectric material. The insulated electrode may be formed in any suitable manner. For example, in the embodiment of FIG. 2, the conductive portion 202 of the insulated storage electrode 110 may be formed on the same layer in the metal stack 102B as the pixel electrode 108, and an insulator may be deposited on top of the conductive portion 202 of the insulated storage electrode 110. In some instances, this may be formed by depositing an insulating layer over both the conductive portion 202 and the pixel electrode 108, and selectively etching to remove the portion of the insulating layer that covers the pixel electrode 108.

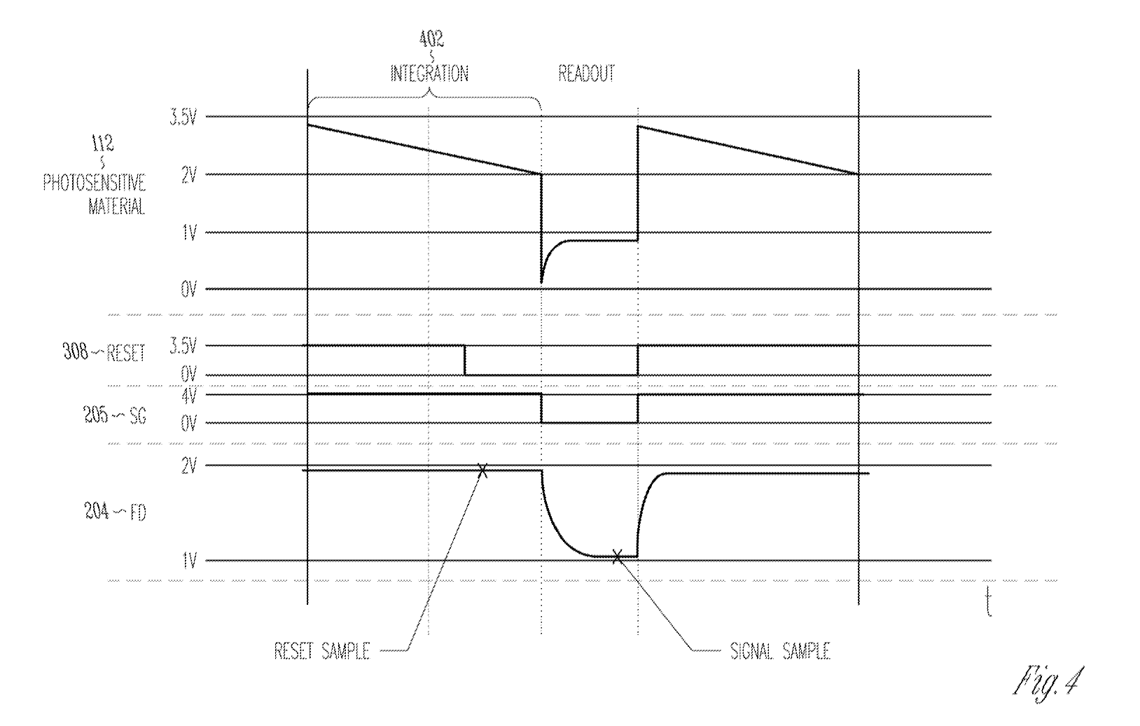

Alternatively, the insulated storage electrode 110 may be configured such that the conductive portion 202 is in a different layer of the metal stack 102B as pixel electrode 108. For example, FIG. 5 shows on such embodiment (identical to the embodiment of FIG. 2 aside from the conductive portion 202A and insulator 202B, and labeled accordingly) in which the conductive portion 202A of the insulated storage electrode 110 comprises a lower level circuit interconnection material, with the insulating material of the insulated electrode 110 including an inter-metal dielectric 203A of the metal stack 102B. It should be appreciated that in variations where a pixel comprises a plurality of capacitively coupled electrodes (each including a conductive portion and an insulator separating the conductive portion from the photosensitive material layer 112), the conductive portions may each be in the same layer of the metal stack as each other (which may or may not be the same metal stack layer as the pixel electrode) or alternatively different conductive portions may be in different metal stack layers.

As mentioned above, the insulated storage electrode 110 may be used to temporarily hold charge relative to the photosensitive material layer 112. When illuminated with oncoming light (e.g., through an encapsulant material 206 (if present) and/or electrode 114)), the photosensitive material layer 112 may absorb light, producing photoelectrons/hole pairs. If a predetermined bias is applied to the insulated storage electrode 110 (e.g., via a storage gate), photoelectrons or holes (depending on the configuration of the device) may drift towards or otherwise be pulled toward the insulated electrode 110. If the electric bias of the insulated storage electrode 110 is higher than the bias of the electrode 108 and both are higher than the bias on the top electrode 114, photoelectrons may accumulate in the photosensitive material layer 112 near a region closest to the insulated storage electrode 110. Conversely, if the electric bias of the insulated storage electrode 110 is be lower than the bias of the pixel electrode 108, and both are lower than the bias electrode 114, photoelectrons may accumulate in the photosensitive material layer 112 near a region closest to the insulated storage electrode 110. These electrons (or holes) may be held by the insulated storage electrode 110 temporarily, and may be moved to facilitate image collection. For example, at the completion of an integration phase (electron and/or hole collection), the bias of electrode 110 may be changed, such as to allow photo charges collected near the electrode 110 to be transferred from the photosensitive material layer 112 to the pixel electrode 108. While the devices described here may be configured to collect electrons or holes at the pixel electrode depending on biases, for the purposes of illustration biases will be discussed throughout as being used to facilitate electron collection, but it should be appreciated that the same principles would apply to hole collection.

FIGS. 2 and 5 may illustrate just a portion of metal stack 102B as indicated by the squiggly boundary lines. It should be appreciated that the metal stack 102B may span further or less than illustrated FIGS. 2 and 5.

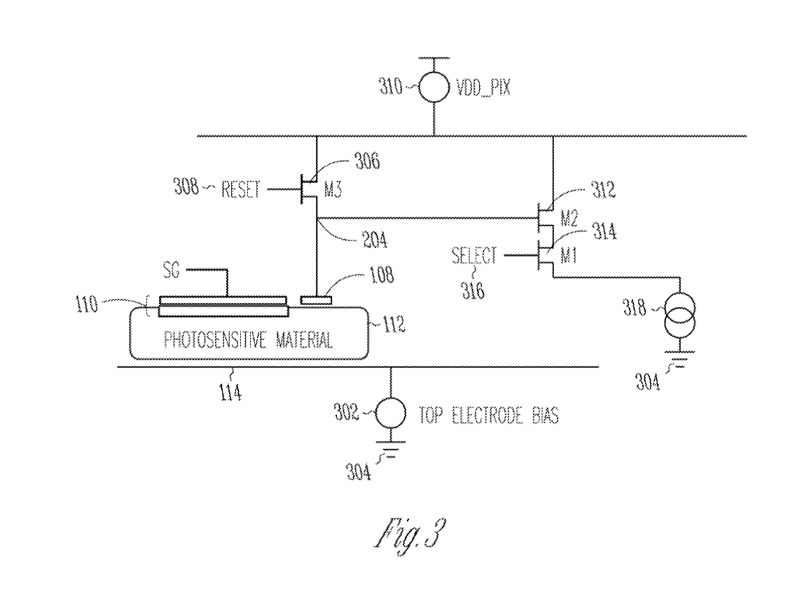

FIG. 3 illustrates, by way of example, a schematic diagram of one embodiment of pixel circuitry 300 of a pixel of an image sensor that may utilize an insulated storage electrode. The pixel circuitry 300 as illustrated includes a bias voltage 302 which may be applied to the top electrode 114 during imaging, an insulated storage electrode 110 connected to a storage gate 205, and a pixel electrode 208 connected to a charge sense node 204. The sense node 204 may be connected to a voltage 310 via a reset switch 306 (which is controlled by a reset signal 308). The reset switch 306 may be used to reset the sense node 204 between frames.

The sense node 204 may further be connected to an input of a source follower switch 312, which may be used to sense changes in the sense node 204. The source follower switch 312 may have its drain connected to voltage 110 and its source connected to a common node with the drain of a select switch 314 (controlled by a select signal 316). The source of the select switch 314 is in turn connected to an output bus (represented by 318 and 304). When the select switch 314 is turned on, changes in the sense node 204 detected by the follower switch 312 will be passed by through the select switch 314 to the bus for further processing. It should be appreciated that the various switches may be integrated into one or more semiconductor layers of the readout circuitry 102, such as described in more detail above.

FIG. 4 illustrates, by way of example, an embodiment of graphs of voltage versus time for a variety of components of the circuitry 300 which illustrate how the image collection and readout of a pixel may occur. The voltage values provided are merely examples used to illustrate a readout function of the circuitry 300. The electrodes 110 and 108 can operate in conjunction to move charges through the photosensitive material layer. The electrode 110 can hold charge in proximity thereto and then charge can be transferred to the electrode 108, such as by applying proper electrical biases to the electrodes 108, 110, and/or 114. The circuitry may operate in other voltage ranges, such as depending on the size of transistors 306, 312, 314, and/or a material of the photosensitive material layer 112.

Initially, a bias may be applied to the photosensitive material layer 112 using the top electrode 114, the pixel electrode 108, and the insulated storage electrode 110. In embodiments of an electron collection device, a charge accumulation region in the photosensitive material layer 112 (e.g., an area of the photosensitive material layer 112 in close proximity with electrode 110, see FIG. 2, for example) might be at an initial potential (e.g., about 3.5V). During light exposure, the potential in the charge accumulation region may drop to a lower potential, such as 2V, as photons are absorbed and electron-hole pairs are created, as shown in FIG. 4. This time of charge accumulation is referred to as integration 402. The amount of potential change in the charge accumulation region can depend on an amount of light absorbed. During integration, the storage gate may be held at a first voltage (e.g., 4 V), which may cause created electrons to be held in the charge accumulation region in the photosensitive material layer 112.

Initially during integration, the charge sense node may be held at a reset value. At or near the end of integration 402 the charge sense node may be released from reset by switching a gate of the reset transistor 306 to a lower voltage. At or around this time, the reset level of the sense node (e.g., sense node 204) can be read out (using the source follower switch 312 and the select switch 314) and stored (e.g., to be used in a correlated double sample (CDS) operation).

At the end of integration, the storage gate potential may be switch from the first voltage to a lower voltage, for example from 4V to 0V. Due to the capacitive coupling of electrode 110 to the photosensitive material layer 112, the charge accumulation potential near the electrode 110 may drop by an amount proportional to a ratio of the capacitance of the photosensitive material layer 112 to a total capacitance of the electrode 110 plus the capacitance of the photosensitive material layer 112. In the example shown in FIG. 4, the ratio is about 1:2 or about 1V to 2V.

At or around this time a region in close proximity of insulated storage electrode 110 will be at lower potential than the pixel electrode 108 (and the charge sense node 204) and electrons that were previously held by the insulated storage electrode 110 will therefore drift into the sense node 204 via the pixel electrode 108, thereby changing the potential of the sense node 204. This change in potential of the sense node 204 can be sampled and saved (again using the source follower switch 312 and the select switch 314). In instances where the image sensor device performs a CDS operation, this stored potential may be subtracted from the previously stored reset level. Following the readout, the biases may be returned to their initial configurations and a new integration period may begin. As mentioned above, the same general operation applies to a holes collection device, in which all potentials are inverted.

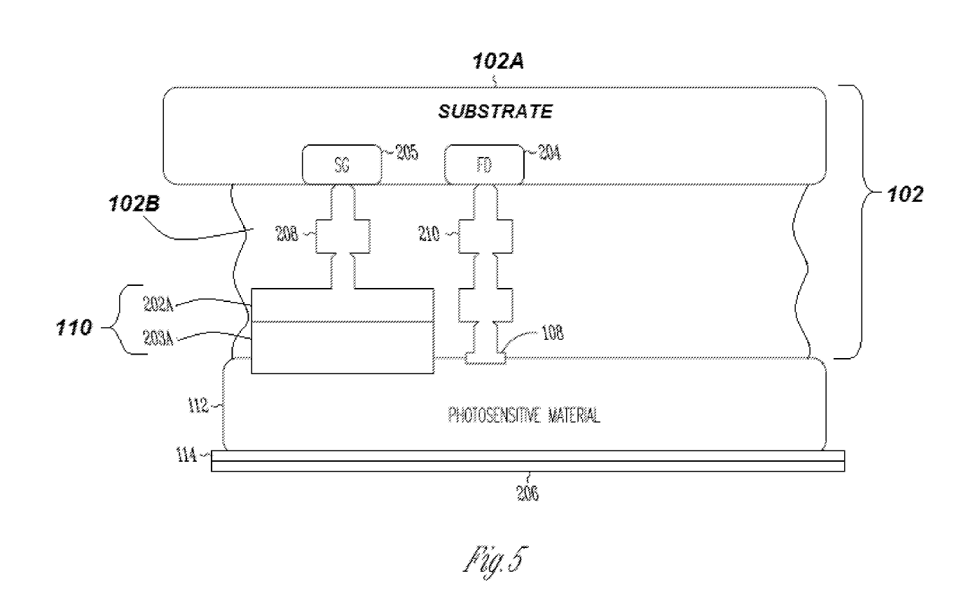

FIG. 6 illustrates, by way of example, a diagram of another embodiment of pixel circuitry. The embodiment of FIG. 6 has similar components (labeled similarly) to those shown in FIG. 2, except that the pixel includes a transmit electrode 604 between insulated storage electrode 110 and the pixel electrode 108. The embodiment of FIG. 6 also includes a bias electrode 602 which may separate the insulated storage electrode 110 and a pixel electrode (or other electrode) of an adjacent pixel, as will be discussed in more detail below. It should be appreciated that embodiments of the inventions described here include embodiments including a transfer electrode (and associated circuitry) but not a barrier electrode as well as embodiments that include a barrier electrode (and associated circuitry) but not a transfer electrode.

In embodiments that include a transfer electrode 604, the readout circuitry 102 may include a transfer gate 610 which may be used to control the potential of the transfer electrode 604. In instances where the readout circuitry includes a metal stack (606 in FIG. 6), the metal stack may include interconnect circuitry to connect the transfer gate 610 to the transfer electrode 604. As with insulated storage electrode 110, the transfer electrode 604 may be an insulated electrode that is capacitively coupled to the photosensitive material layer 112 (although it should be appreciated that the conductive portion of the transfer electrode 604 is in a same or different layer as the conductive portion of the storage electrode 110).

Similarly, in embodiments that include a barrier electrode 602, the readout circuitry 102 may include a barrier gate 612 which may be used to control the potential of the barrier electrode 612. In instances where the readout circuitry 102 includes a metal stack 606, the metal stack may include interconnect circuitry to connect the barrier gate 612 to the barrier electrode 602. As with insulated storage electrode 110, the barrier electrode 602 may be an insulated electrode that is capacitively coupled to the photosensitive material layer 112 (although it should be appreciated that the conductive portion of the barrier electrode 602 is in a same or different layer as the conductive portion of the storage electrode 110).

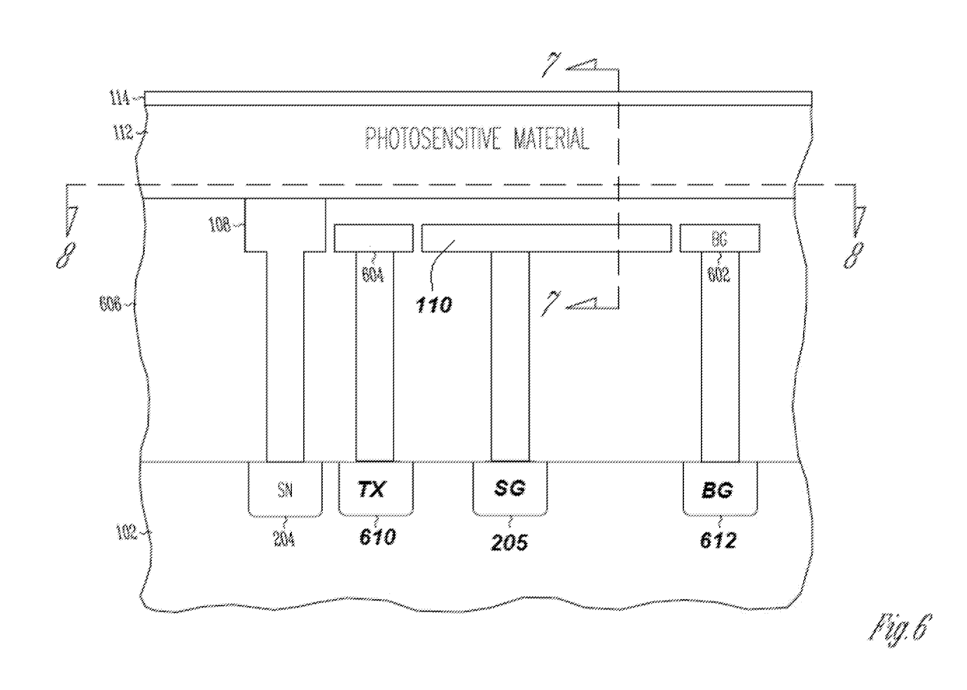

FIGS. 7 and 8 illustrate, by way of example respective diagrams of a principle of operation of circuitry (e.g., charge transfer pixel that includes circuitry of FIG. 6) by which the transfer electrode 604 may be used to facilitate charge transfer between the storage electrode 110 and the sense node 204. FIG. 7 shows a potential distribution in or near the photosensitive material layer 112 and charge transfer into the sense node 204 in a cross-section indicated by arrows labelled “7” in FIG. 6.

The storage gate 205 may bias the insulated storage electrode 110 to create a potential well for collecting photo charge in the photosensitive material layer 112 (such as discussed in more detail above). The barrier gate 612 may bias the barrier electrode 602 to a lower potential (relative to the potential of the storage electrode 110), where the potential difference may act to build a barrier to electron flow in the photosensitive material layer 112 from an area near the storage electrode 110 to an area near the electrode of an adjacent pixel (which could result in pixel-to-pixel crosstalk). Similarly, the transfer gate 610 may bias the transfer electrode 610 may be biased to a lower potential (relative to the potential of the storage electrode 110), where the potential difference may act to build a barrier to electron flow in the photosensitive material layer 112 from an area near the storage electrode 110 to the pixel electrode 108 (which may reduce electrons being prematurely transferred to the charge sense node 204). At the end of integration, charge may be transferred from the storage electrode 110 to the pixel electrode 108 by raising the potential of the transfer electrode 604.

FIG. 8 shows an energy band diagram in a cross-section indicated by arrows labelled “8” in FIG. 6. This example is for electron collection but similar principles may be applied to hole collection. The photosensitive material layer 112 on the top of the readout circuitry (represented by 606) may have energy bands that vary depending on the sub-layers (e.g., with a sub-layer 608 having a wider band). In the beginning of integration period there is generally negligible or no mobile charge under the storage electrode 110. The voltage applied to the storage electrode 110 can be divided between the insulating portion of the electrode and the photosensitive material layer 112. A dielectric material with a higher capacitance can provide better control efficiency.

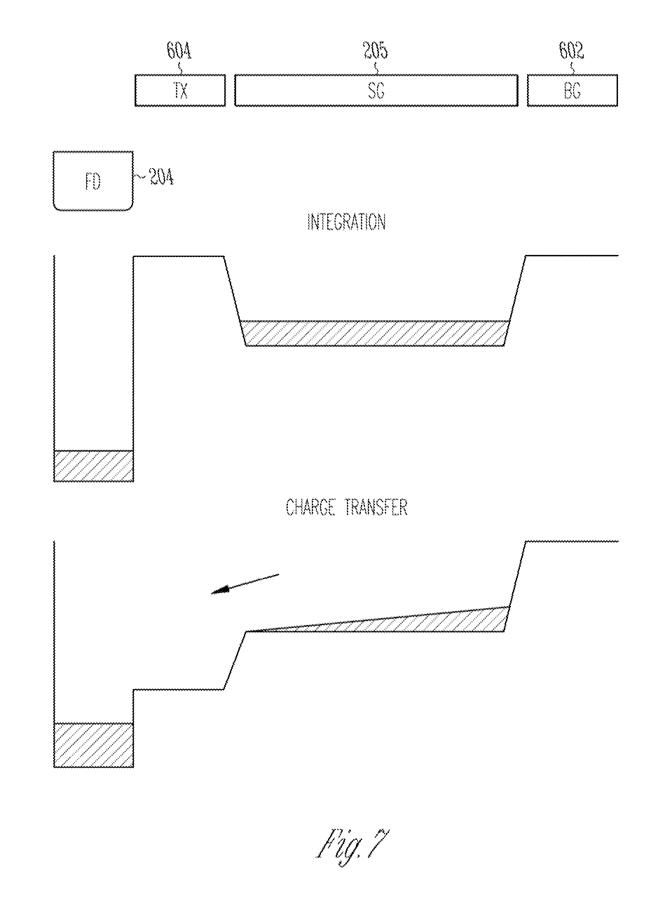

FIGS. 9-12 illustrate, by way of example, respective perspective view diagrams of embodiments of different configurations of electrode interfaces with one or more pixels. FIG. 9 illustrates one embodiment in which a pixel comprises a pixel electrode 108, an insulated charged storage electrode (shown in FIG. 9 as storage gate 205), a transfer electrode 604 positioned between the pixel electrode 108 and the storage electrode, and a barrier electrode 602. In this embodiment, the barrier electrode 602 may surround the pixel, storage, and transfer electrodes. While shown in FIG. 9 as completely surrounding these electrodes, it should be appreciated that the barrier electrode 602 may only partially surround the electrodes.

FIG. 10 provides a top view illustration of a variation of a pixel in which the pixel comprises a pixel electrode 108, a storage electrode (e.g., shown as storage gate 205), and a transfer electrode 604, but does not include a barrier electrode.

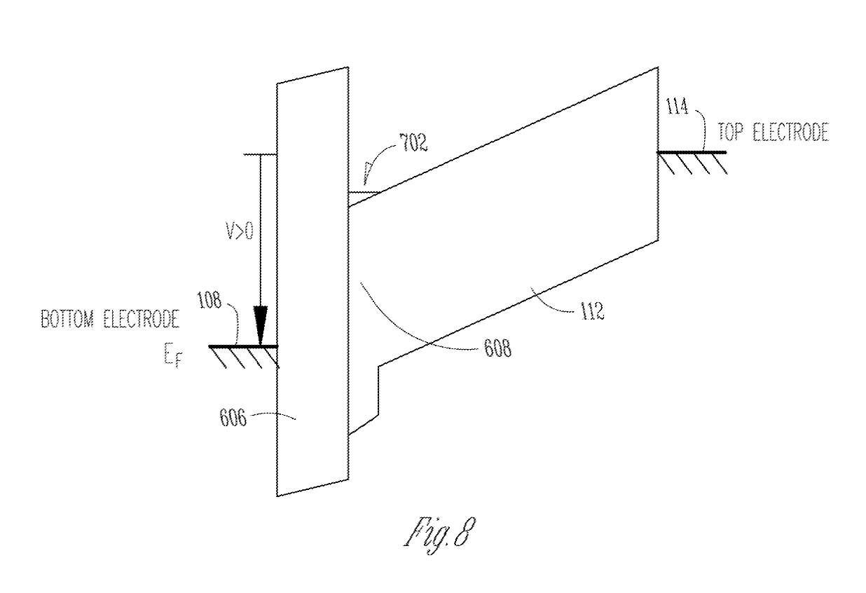

In some instances, multiple pixels may share a common pixel electrode. For example, FIG. 11 illustrates, by way of example, a two-way shared pixel circuitry. In the embodiment of FIG. 11, two pixels share a common pixel electrode 108. In this embodiment, a first transfer electrode 604A may be positioned between a first storage electrode (e.g., shown as storage gate 205A) and the pixel electrode while a second transfer electrode 604B may be positioned between a second storage electrode (e.g., shown as storage gate 205B) and the pixel electrode 108. Although not shown in FIG. 11, some embodiments include a barrier electrode at least partially surrounding the pixel pair.

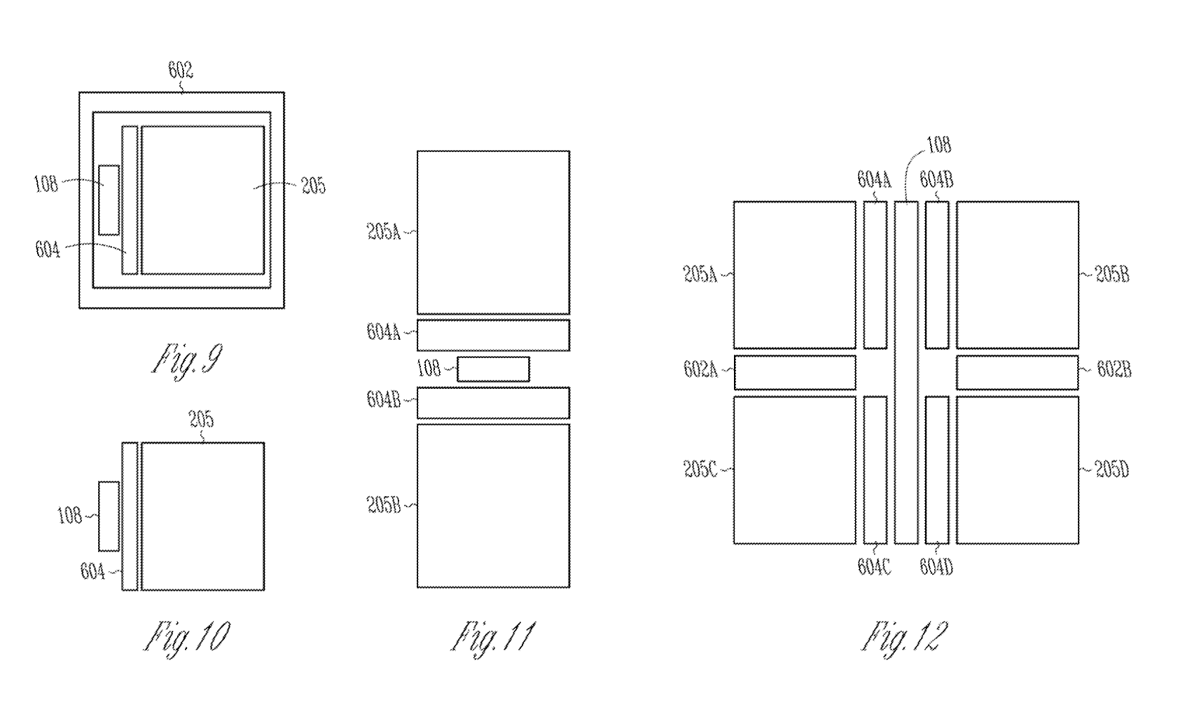

FIG. 12 illustrates, by way of example, a four-way shared pixel circuitry. The electrode 108 is shared between four pixels in the embodiment of FIG. 12. In these embodiments, a first pair of pixels may include a first pixel having a first transfer electrode 604A separating first storage electrode (e.g., shown as storage gate 205A) from the pixel electrode 108 and a second pixel having a second transfer electrode 604C separating second storage electrode (e.g., shown as storage gate 205C) from the pixel electrode 108. At least a portion of the first and second pixels may be separated by a first barrier electrode 602A shared between the pixels (only the storage electrodes represented by storage gates 205A and 205B are shown as being separated by the first barrier electrode 602A, although it should be appreciated that the transfer electrodes 604A and 604C may also be separated by the first barrier electrode 602A). Similarly, a second pair of pixels may include a first pixel having a first transfer electrode 604B separating first storage electrode (e.g., shown as storage gate 205B) from the pixel electrode 108 and a second pixel having a second transfer electrode 604D separating second storage electrode (e.g., shown as storage gate 205D) from the pixel electrode 108. At least a portion of the first and second pixels may be separated by a second barrier electrode 602B shared between the pixels (only the storage electrodes represented by storage gates 205A and 205B are shown as being separated by the first barrier electrode 602A, although it should be appreciated that the transfer electrodes 604A and 604C may also be separated by the first barrier electrode 602A). It should also be appreciated that an additional barrier electrode may also at least partially surround the connected pixels (and is some instance may be connected to the first and/or second barrier electrodes).

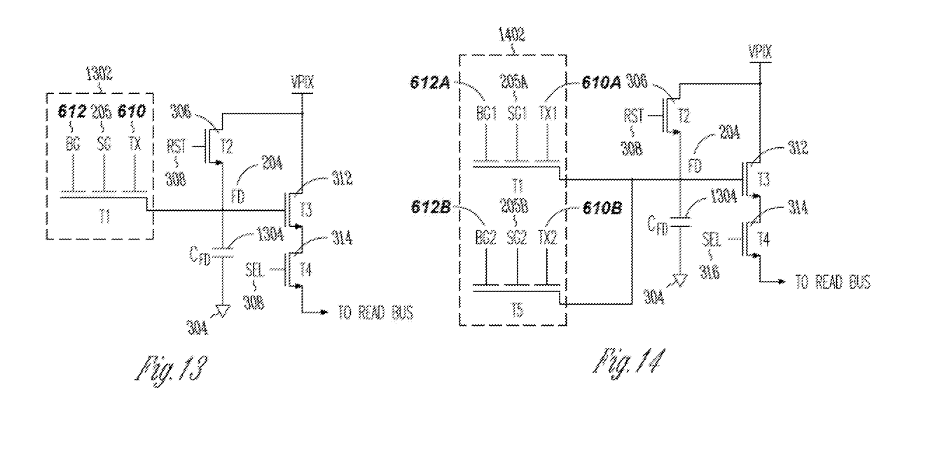

FIGS. 13 and 14 illustrate, by way of example, diagrams of embodiments of pixel circuitry that may be used with the one- and two-pixel pixel arrangements similar to those described above with respect to FIG. 9 and a variation of FIG. 10 in which the pixels include barrier electrodes. The embodiment of FIG. 13 includes a three gate (e.g., barrier gate 602, storage gate 205, and transfer (TX) gate 604, charge-coupled device (CCD) 1302. The CCD 1302 is electrically coupled to the sense node 204. The circuitry of FIG. 13 further includes reset switch 306, source follow switch 312, and select switch 314, which may be operated in a similar manner described above with respect to FIG. 3 to read out charge information from the sense node 204. The embodiment of FIG. 14 includes a two-way shared pixel. In the embodiment of FIG. 14 two CCD structures 1402 share a common sense node 204. The two CCDs 1402 include a first CCD comprising BG 602A, SG 205, and TX gate 604A and a second CCD comprising BG 602B, SG 205, and TX gate 604B. The potential of the storage electrode may be moved between different levels to i) control charge accumulation near the storage electrode and ii) facilitate charge transfer to the sense node (as discussed above with respect to claim 7), and the remaining circuitry may be used to readout information from the sense node.

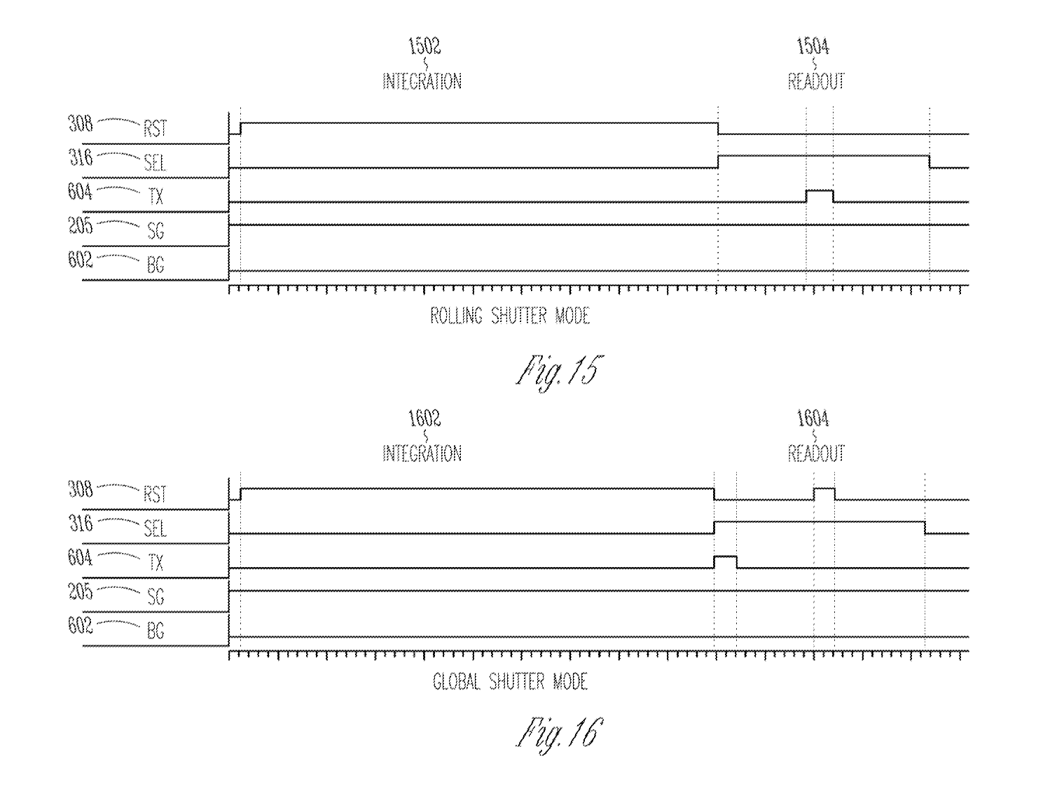

FIGS. 15 and 16 illustrate, by way of example, respective embodiments of a variety of voltages versus time of pixel circuitry discussed herein. The timing diagrams of FIGS. 15 and 16 illustrate voltages of pixel circuitry in a low-noise rolling shutter mode and global shutter mode, respectively. During integration 1502 time, the RST signal 308 can be kept at high level to maintain a constant potential on the sense node 204. At or before the time pixel readout starts, the reset (RST) signal 308 can be driven low and the sense node 204 can float. The select (SEL) signal 316 can go high, turning on the select switch 314 and connect the pixel source follower switch 312 can be to a read bus. In rolling shutter mode, the reset level of the sense node 204 can be read out first (a voltage level of the sense node 204 at or around the time the reset signal 308 is set low). The voltage on the transfer gate 604 can be set high and photo charge can be transferred to the sense node 204 via the pixel electrode. Signal level measurement (e.g., readout 1504) can follow the charge transfer. The readout 1504 sequence allows CDS operation. In case of global shutter mode signal charge transfer happens before reset level readout 1604.

### Additional Notes and Examples

The present subject matter can be described by way of several examples.

Example 1 can include or use subject matter (such as an apparatus, a method, a means for performing acts, or a device readable memory including instructions that, when performed by the device, can cause the device to perform acts), such as can include or use an image sensor device including pixel circuitry, the pixel circuitry comprising a photosensitive material layer, circuitry including first, second, and third electrodes and a storage device, the first electrode on a first surface of the photosensitive material layer and the second and third electrodes on a second surface of the photosensitive material layer, the first surface opposite the second surface, electrical interconnect circuitry electrically coupling the second electrode and the storage device, and a dielectric material situated between the third electrode and the photosensitive material layer.

Example 2 can include or use, or can optionally be combined with the subject matter of Example 1, to optionally include or use, wherein the pixel circuitry further comprises a second storage device on the second surface of the photosensitive material layer, and second interconnect circuitry electrically coupling the third electrode to the second storage device.

Example 3 can include or use, or can optionally be combined with the subject matter of Example 2, to optionally include or use, wherein the pixel circuitry further comprises a transfer gate situated between the second storage device and the second electrode, and a second dielectric material situated between the second electrode and the transfer electrode.

Example 4 can include or use, or can optionally be combined with the subject matter of Example 3, to optionally include or use, wherein the pixel circuitry further comprises multiple transfer gates capacitively coupled to the second electrode.

Example 5 can include or use, or can optionally be combined with the subject matter of at least one of Examples 2-5, to optionally include or use, wherein the pixel circuitry further comprises a barrier gate, the second storage device situated between the barrier gate and the second electrode.

Example 6 can include or use, or can optionally be combined with the subject matter of at least one of Examples 1-5, to optionally include or use, wherein the pixel circuitry further comprises a passivation material situated between the second electrode and the photosensitive material layer.

Example 7 can include or use, or can optionally be combined with the subject matter of at least one of Examples 1-6, to optionally include or use, wherein the first electrode is optically transparent.

Example 8 can include or use, or can optionally be combined with the subject matter of at least one of Examples 1-7, to optionally include or use, wherein the pixel circuitry further comprises a third dielectric material situated on the second surface of the photosensitive material layer, wherein the second and third electrodes are situated on, or at least partially in, the third dielectric material.

Example 9 can include or use, or can optionally be combined with the subject matter of Example 8, to optionally include or use a semiconductor material situated on the third dielectric material.

Example 10 can include or use, or can optionally be combined with the subject matter of Example 9, to optionally include or use, wherein the semiconductor material includes an indirect bandgap semiconductor material and the photosensitive material layer includes a direct bandgap semiconductor material.

Example 11 can include or use subject matter (such as an apparatus, a method, a means for performing acts, or a device readable memory including instructions that, when performed by the device, can cause the device to perform acts), such as can include or use pixel circuitry of an imaging device, the pixel circuitry comprising a photosensitive material layer, a charge sense gate, a direct current electrode on the photosensitive material layer and electrically coupled to the floating diffusion gate, and an insulated electrode on the photosensitive material layer and capacitively coupled to the photosensitive material layer when an electrical bias is applied to the insulated electrode causing charges to accumulate on a portion of the photosensitive material layer in proximity to the insulated electrode.

Example 12 can include or use, or can optionally be combined with the subject matter of Example 11, to optionally include or use, a storage gate electrically coupled to the insulated electrode.

Example 13 can include or use, or can optionally be combined with the subject matter of Example 12, to optionally include or use, a transfer gate situated between the storage gate and the direct current electrode.

Example 14 can include or use, or can optionally be combined with the subject matter of Example 13, to optionally include or use, multiple transfer gates capacitively coupled to the direct current electrode.

Example 15 can include or use, or can optionally be combined with the subject matter of at least one of Examples 12-14, to optionally include or use, a barrier gate, the storage gate situated between the barrier gate and the direct current electrode.

Example 16 can include or use subject matter (such as an apparatus, a method, a means for performing acts, or a device readable memory including instructions that, when performed by the device, can cause the device to perform acts), such as can include or use a method of determining a pixel value comprising applying a first electrical bias to a direct current electrode of an image sensing device, applying a second, different electrical bias to an insulated electrode of the image sensing device, collecting, at a photosensitive material layer and in proximity of the insulated electrode, electrons or holes, applying a third, different electrical bias to a gate of a transistor electrically coupled to the direct current electrode, after applying the third electrical bias, recording a first voltage potential at the direct current electrode, applying a fourth electrical bias to the insulated electrode, after applying the third electrical bias, recording a second voltage potential at the direct current electrode, and determining a difference between the first and second voltages.

Example 17 can include or use, or can optionally be combined with the subject matter of Example 16, to optionally include or use, wherein the transistor is a first transistor and the method further comprises at or around a time of applying the third electrical bias to the first transistor, applying a fifth electrical bias to a gate of a second transistor electrically coupled in parallel with the transistor.

Example 18 can include or use, or can optionally be combined with the subject matter of Example 17, to optionally include or use, after applying the fifth electrical bias, applying a sixth bias to a transfer gate capacitively coupled to the direct current electrode.

Example 19 can include or use, or can optionally be combined with the subject matter of Example 17, to optionally include or use, at or around a time of applying the third electrical bias to the first transistor, applying a sixth electrical bias to a transfer gate capacitively coupled to the direct current electrode.

Example 20 can include or use, or can optionally be combined with the subject matter of Example 19, to optionally include or use, removing the bias applied to the first transistor and the transfer gate, and re-applying the bias to the first transistor.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in this document, the terms “first,” “second,” and “third,” etc. are used merely as labels, and are not intended to impose numerical requirements on their objects.

From the foregoing, it will be observed that numerous variations and modifications can be effected without departing from the scope of the invention. It is to be understood that no limitation with respect to the specific apparatus illustrated herein is intended or should be inferred. It is, of course, intended to cover by the appended claims all such modifications as fall within the scope of the claims. Although a few embodiments have been described in detail above, other modifications are possible.

What is claimed is:

1. An image sensor device including pixel circuitry, the pixel circuitry comprising:
a photosensitive material layer;
circuitry including first, second, and third electrodes and a storage device, the first electrode on a first surface of the photosensitive material layer and the second and third electrodes on a second surface of the photosensitive material layer, the first surface opposite the second surface;
electrical interconnect circuitry electrically coupling the second electrode and the storage device, and
a dielectric material situated between the third electrode and the photosensitive material layer.

2. The image sensor device of claim 1, wherein the pixel circuitry further comprises:
a second storage device on the second surface of the photosensitive material layer; and
second interconnect circuitry electrically coupling the third electrode to the second storage device.

3. The image sensor device of claim 2, wherein the pixel circuitry further comprises:
a transfer gate situated between the second storage device and the second electrode; and
a second dielectric material situated between the second electrode and the transfer electrode.

4. The image sensor device of claim 3, wherein the pixel circuitry further comprises multiple transfer gates capacitively coupled to the second electrode.

5. The image sensor device of claim 2, wherein the pixel circuitry further comprises a barrier gate, the second storage device situated between the barrier gate and the second electrode.

6. The image sensor device of claim 1, wherein the pixel circuitry further comprises a passivation material situated between the second electrode and the photosensitive material layer.

7. The image sensor device of claim 1, wherein the first electrode is optically transparent.

8. The image sensor device of claim 1, wherein the pixel circuitry further comprises a third dielectric material situated on the second surface of the photosensitive material layer, wherein the second and third electrodes are situated on, or at least partially in, the third dielectric material.

9. The image sensor device of claim 8, further comprising a semiconductor material situated on the third dielectric material.

10. The image sensor device of claim 9, wherein the semiconductor material includes an indirect bandgap semiconductor material and the photosensitive material layer includes a direct bandgap semiconductor material.

11. Pixel circuitry of an imaging device, the pixel circuitry comprising:
a photosensitive material layer;
a charge sense gate;
a direct current electrode on the photosensitive material layer and electrically coupled to the floating diffusion gate; and
an insulated electrode on the photosensitive material layer and capacitively coupled to the photosensitive material layer when an electrical bias is applied to the insulated electrode causing charges to accumulate on a portion of the photosensitive material layer in proximity to the insulated electrode.

12. The pixel circuitry of claim 11, further comprising a storage gate electrically coupled to the insulated electrode.

13. The pixel circuitry of claim 12, further comprising a transfer gate situated between the storage gate and the direct current electrode.

14. The pixel circuitry of claim 13, further comprising multiple transfer gates capacitively coupled to the direct current electrode.

15. The pixel circuitry of claim 12, further comprising a barrier gate, the storage gate situated between the barrier gate and the direct current electrode.

16. A method of determining a pixel value comprising:
applying a first electrical bias to a direct current electrode of an image sensing device;
applying a second, different electrical bias to an insulated electrode of the image sensing device;
collecting, at a photosensitive material layer and in proximity of the insulated electrode, electrons or holes;
applying a third, different electrical bias to a gate of a transistor electrically coupled to the direct current electrode;
after applying the third electrical bias, recording a first voltage potential at the direct current electrode;
applying a fourth electrical bias to the insulated electrode;
after applying the third electrical bias, recording a second voltage potential at the direct current electrode; and
determining a difference between the first and second voltages.

17. The method of claim 16, wherein the transistor is a first transistor and the method further comprises:
at or around a time of applying the third electrical bias to the first transistor, applying a fifth electrical bias to a gate of a second transistor electrically coupled in parallel with the transistor.

18. The method of claim 17, further comprising:
after applying the fifth electrical bias, applying a sixth bias to a transfer gate capacitively coupled to the direct current electrode.

19. The method of claim 17, further comprising:
at or around a time of applying the third electrical bias to the first transistor, applying a sixth electrical bias to a transfer gate capacitively coupled to the direct current electrode.

20. The method of claim 19, further comprising:
removing the bias applied to the first transistor and the transfer gate; and
re-applying the bias to the first transistor.
